(19) United States
(12) Patent Application Publication
(10) Pub. No.: US 2010/0159697 A1
(43) Pub. Date: Jun. 24, 2010

(54) METHOD FOR MANUFACTURING SEMICONDUCTOR DEVICE

(76) Inventor: Chung-Kyung Jung, Anyang-si (KR)

Correspondence Address: SHERR & VAUGHN, PLLC, 620 HERNDON PARKWAY, SUITE 320, HERNDON, VA, 20170, US

(21) Appl. No.: 12/633,628

(22) Filed: Dec. 8, 2009

(30) Foreign Application Priority Data
Dec. 22, 2008 (KR) 10-2008-0130943

(51) Int. Cl. H01L 21/306; H01L 21/3065

(52) U.S. Cl. 438/692; 438/702; 257/E21.218; 257/E21.219; 257/E21.23

(57) ABSTRACT

A method of manufacturing a semiconductor device may include forming a first oxide film, a nitride film and/or a second oxide film over a substrate, and may include forming a trench over a semiconductor substrate by etching a portion of a first oxide film, a nitride film, a second oxide film and/or a semiconductor substrate. A method of manufacturing a semiconductor device may include performing wet etching to form a divot, which may be performed over a semiconductor substrate having a trench, and/or which may expose a portion of a nitride film. A method of manufacturing a semiconductor device may include removing a second oxide film having a portion thereof etched and a portion of a first oxide film exposed by a divot, while rounding upper edge portions of a trench using a mixed solution of deionized water and HF. A semiconductor device formed by a method is disclosed.

The present application claims priority under 35 U.S.C. 119 to Korean Patent Application 10-2008-0130943 (filed on Dec. 22, 2008) which is hereby incorporated by reference in its entirety.

### BACKGROUND

Embodiments relate to electric devices. Some embodiments relate to semiconductor devices and a method of manufacturing semiconductor devices.

A MOSFET device, such as a Extended Drain MOS (EDMOS), may have a structure in which relatively highly doped N-type impurity and relatively lightly doped P-type impurity are arranged periodically to form a floating region. A EDMOS may withstand a relatively high voltage and/or may have a relatively low impedance. These properties may result from a relatively sharp increase of a depletion layer at a PN junction when a voltage is applied to a drain where a PN junction is formed. However, in view of its structure, a EDMOS may have a leakage current which may hinder driving force and/or impair relative efficiency of a product.

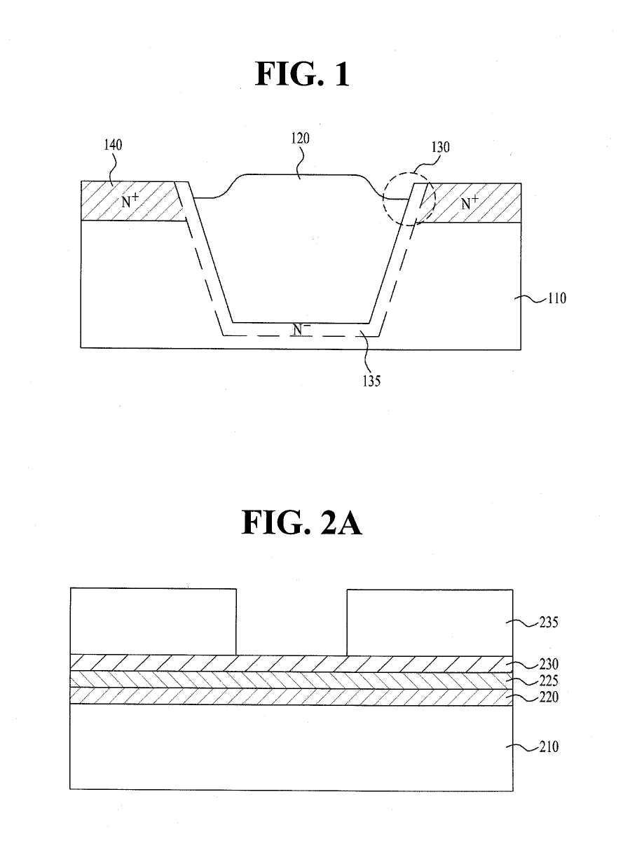

FIG. 1 illustrates a device isolation film in a EDMOS structure. As illustrated in FIG. 1, N⁺ source and drain regions 140 may be formed at an active region. N⁻ regions 135 may be formed between a device isolation film 120 and source and drain regions 140. However, there may be a leakage current approximately in the vicinity of an upper edge 130 of device isolating film 120, which may drop a driving voltage.

Accordingly, there is a need for a semiconductor device and a method of manufacturing the same which may substantially prevent a leakage current from occurring and/or which may relatively improve a MOSFET characteristic.

### SUMMARY

Embodiments relate to a semiconductor device and a method of manufacturing a semiconductor device. According to embodiments, a semiconductor device and a method of manufacturing a semiconductor device may substantially prevent a leakage current from occurring. In embodiments, a semiconductor device and a method of manufacturing the same may improve a MOSFET characteristic. In embodiments, an edge portion in contact with a device isolating film at an active region may be rounded by wet etching and may relatively reduce a leakage current.

Embodiments relate to a method of manufacturing a semiconductor device. According to embodiments, a method of manufacturing a semiconductor device may include forming a first oxide film, a nitride film and/or a second oxide film over a substrate, such as a semiconductor substrate. In embodiments, a method of manufacturing a semiconductor device may include forming a trench over a semiconductor substrate by for example etching. In embodiments, a portion of a first oxide film, a nitride film, a second oxide film and/or a semiconductor substrate may be etched.

According to embodiments, a method of manufacturing a semiconductor device may include performing wet etching over a semiconductor substrate having a trench formed thereover. In embodiments, performing wet etching may etch portions of a nitride film exposed during etching to form a trench, and/or may form divots. In embodiments, a method of manufacturing a semiconductor device may include removing a second oxide film having a portion thereof etched and portions of a first oxide film exposed by divots, while rounding upper edge portions of a trench using, for example, a mixed solution of deionized water and HF.

### DRAWINGS

Example FIG. 1 illustrates a device isolation film in a EDMOS structure.

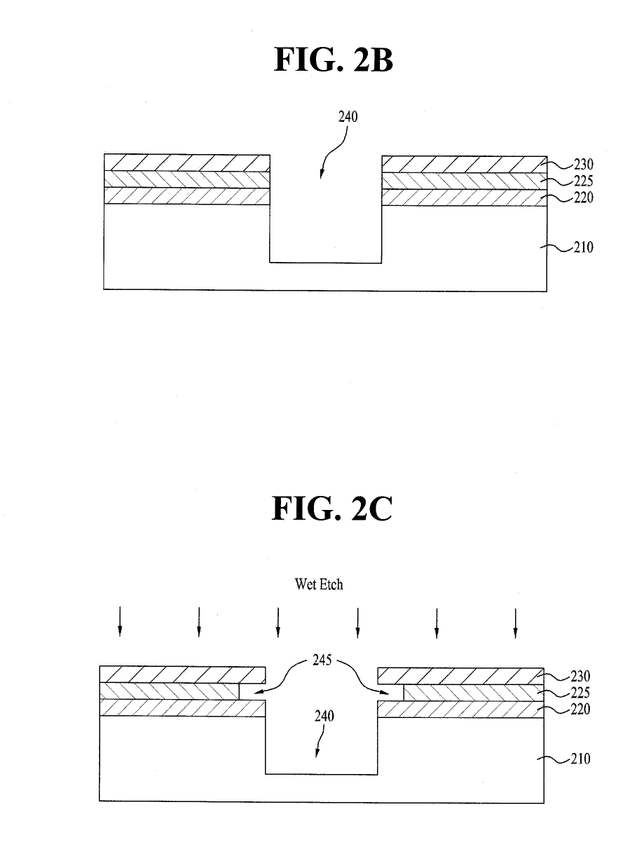

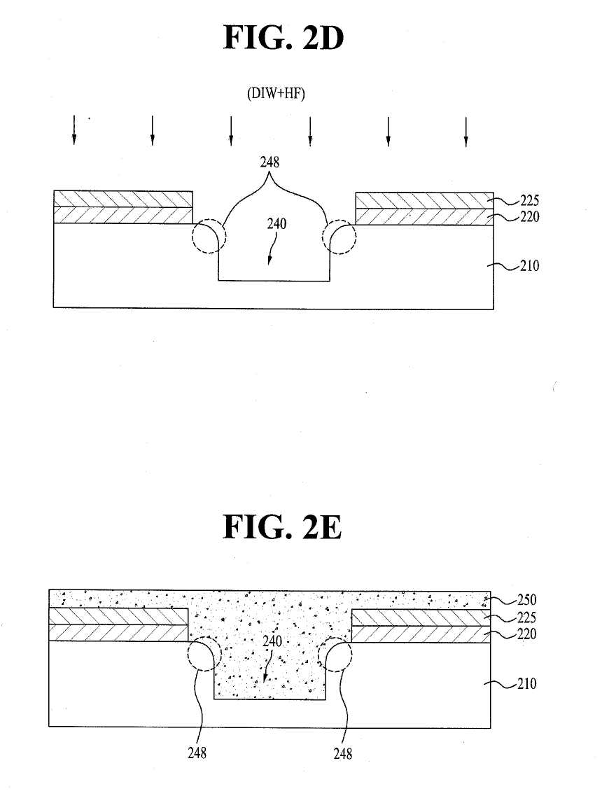

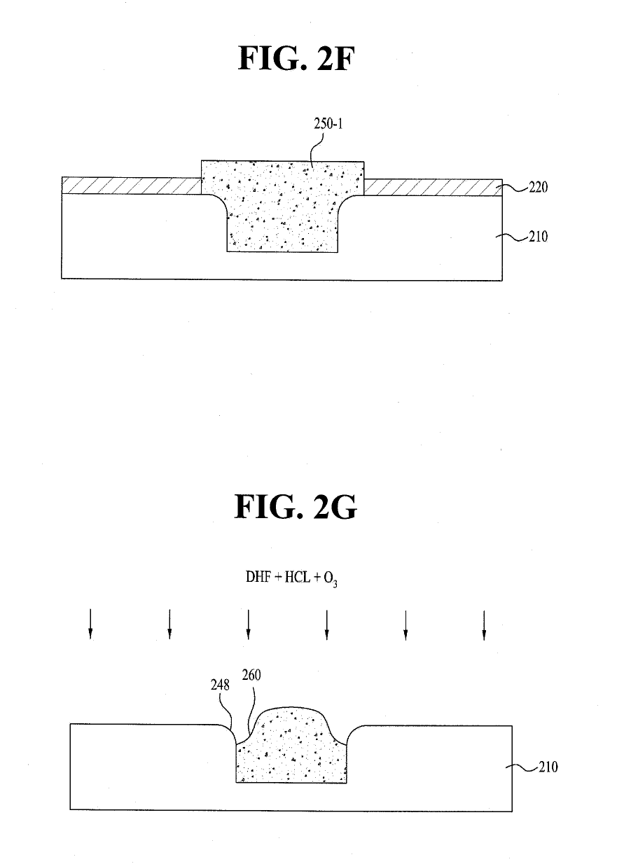

Example FIG. 2A to FIG. 2G illustrate cross section views of a method of manufacturing a semiconductor device in accordance with embodiments.

### DESCRIPTION

Embodiments relate to a method of manufacturing a semiconductor device. Referring to example FIG. 2A to FIG. 2G, a method of manufacturing a semiconductor device in accordance with embodiments is illustrated. Referring to FIG. 2A, first oxide film 220 may be formed over a substrate, such as a semiconductor substrate, by thermal oxidation or Chemical Vapor Deposition (CVD). In embodiments, nitride film 225 may be deposited over first oxide film 220 by CVD. In embodiments, second oxide film 230 may be formed over nitride film 225 by CVD.

According to embodiments, photoresist pattern 235 may be formed over second oxide film 230 to form a trench. In embodiments, photoresist may be coated over second oxide film 230 and may be subjected to exposure and development to form photoresist pattern 235. In embodiments, a region of second oxide film 230 may be exposed.

Referring to FIG. 2B, trench 240 may be formed over semiconductor substrate 210 using photoresist pattern 235. According to embodiments, photoresist pattern 235 may be used to etch second oxide film 230, nitride film 225, first oxide film 220, and/or semiconductor substrate 210, for example in succession, to form trench 240. In embodiments, photoresist pattern 235 remaining after etching may be removed, for example by ashing or stripping.

According to embodiments, second oxide film 230, nitride film 225, and/or first oxide film 220 may be etched, for example in succession, using photoresist pattern 235 as an etch mask, to expose semiconductor substrate 210. In embodiments, photoresist pattern 235 remaining after etching may be removed, for example by ashing or stripping. In embodiments, a surface of semiconductor substrate 210 may be subjected to isotropic etching, for example reactive ion etching, to form trench 240.

According to embodiments, a semiconductor substrate such as a silicon substrate may have an etch rate greater relative to second oxide film 230. In embodiments, second oxide film 230 may be deposited to have a thickness to serve as an etch barrier, sufficient to form trench 240 over semiconductor substrate 210.

Referring to FIG. 2C, semiconductor substrate 210 may include trench 240 formed therover. According to embodiments, semiconductor substrate 210 may be subjected to wet etching, to etch for example portions of nitride film 225. In embodiments, etched portions of nitride film 225 may include exposed portions of nitride film 225 exposed during formation of trench 240. In embodiments, wet etching may form divots 245. In embodiments, exposed portions of nitride film 225 may be wet etched using phosphoric acid (H₃PO₄) to form divots 245. Divots 245 may expose portions of first oxide film 220 adjacent to trench 240 in accordance with embodiments.

Referring to FIG. 2D, semiconductor substrate 210 having divots 245 formed thereover may be dipped in a solution including deionized water (DIW) and HF. According to embodiments, a solution including deionized water DIW and HF may be mixed at a ratio between approximately 100:1 to 200:1. In embodiments, a solution including deionized water DIW and HF may be mixed for a period if time, for an example approximately 5 minutes. Such an operation may refer to a DHF treatment. Using a DHF treatment, second oxide film 230 and/or portions of an exposed first oxide film may be removed. In embodiments, edge portions 248 of an upper side of trench 240 may be rounded, for example at the same time.

Referring to FIG. 2E, third oxide film 250 may be formed over semiconductor substrate 210 such that third oxide film 250 substantially fills trench 240 having upper side edge portions 248 rounded. Referring to FIG. 2F, CMP may be performed over third oxide film 250 until nitride film 225 is exposed and/or to make nitride film 225 substantially flat. According to embodiments, exposed nitride film 225 may be wet etched, for example using phosphoric acid, to remove substantially all nitride film 225. In embodiments, once nitride film 225 is substantially removed for example by wet etching, third oxide film 250-1 disposed over the trench 240 may project beyond first oxide film 220.

Referring to FIG. 2G, first oxide film 220 and projecting third oxide film 250-1 may be etched using a DHF solution. According to embodiments, a DHF solution may include DIW and HF. In embodiments, DIW and HF may be mixed at a ratio between approximately 100:1 to 200:1, and may include HCl and O₃ water. In embodiments, first oxide film 220 and projecting third oxide film 250-1 may be etched using a mixed solution of a DHF solution, HCl and O₃ water.

Referring to FIG. 2G, accounting for etch rates of first oxide film 220 and projecting third oxide film 250-1, a region 260 of third oxide film 250-1 adjacent to rounded trench edges 248 may be rounded. According to embodiments, if an etch rate of third oxide film 250-1 is higher relative to an etch rate of first oxide film 220, in order to etch upper edge portions of third oxide film 250-1 more, an etch profile as illustrated in FIG. 2G may be formed.

According to embodiments, by rounding edge portions 248 by wet etching where an active region, for example including a source region and a drain region, of semiconductor substrate 210 may be in contact with a device isolation film, a leakage current may be reduced. In embodiments, wet etching may not cause plasma damage, which may be caused by dry etching.

It will be obvious and apparent to those skilled in the art that various modifications and variations can be made in the embodiments disclosed. Thus, it is intended that the disclosed embodiments cover the obvious and apparent modifications and variations, provided that they are within the scope of the appended claims and their equivalents.

What is claimed is:

1. A method comprising:
forming a first oxide film, a nitride film and a second oxide film over a semiconductor substrate;
forming a trench over said semiconductor substrate;
performing wet etching over said semiconductor substrate having the trench to form a divot exposing at least a portion of first oxide film;
removing at least a portion of said second oxide film and said portion of said first oxide film exposed by the divot; and
rounding at least one upper edge portion of the trench.

2. The method of claim 1, wherein:
forming the trench comprises etching a portion of said first oxide film, said nitride film, said second oxide film and said semiconductor substrate to expose a portion of said nitride film; and
performing said wet etching comprises wet etching said exposed portion of said nitride film.

3. The method of claim 2, comprising removing the portion of said second oxide film and said portion of said first oxide film exposed by the divot at substantially the same time as said rounding.

4. The method of claim 3, comprising using a solution including deionized water and HF.

5. The method of claim 4, wherein said deionized water and HF are mixed at a ratio between approximately 100:1 to 200:1.

6. The method of claim 1, comprising:
coating a photoresist over said second oxide film and subjecting the photoresist to exposure and development to form a photoresist pattern which exposes a region of said second oxide film;
etching said second oxide film, said nitride film, said first oxide film and said semiconductor substrate in succession using said photoresist pattern as an etch mask to form the trench; and
removing said photoresist pattern remaining after etching comprising using at least one of ashing and stripping.

7. The method of claim 1, comprising:
etching said second oxide film, said nitride film and said first oxide film in succession using a photoresist pattern as an etch mask to expose said semiconductor substrate;
removing said photoresist pattern remaining after etching comprising using at least one of ashing and stripping; and
subjecting a surface of said semiconductor substrate to isotropic etching to form the trench.

8. The method of claim 7, wherein said isotropic etching comprises reactive ion ethcing.

9. The method of claim 1, comprising etching said portion of said nitride film exposed by the divot comprising using phosphoric acid.

10. The method of claim 1, comprising:
forming a third oxide film over said semiconductor substrate to substantially fill the trench having a rounded upper edge portion;
subjecting said third oxide film to CMP until at least a portion of said nitride film is exposed;
removing said portion of said nitride film exposed by CMP to expose a portion of said first oxide film and to form a projecting third oxide film; and
etching said portion of first oxide film exposed and said projecting third oxide film using a DHF solution.

11. The method of claim 10, wherein the DHF solution comprises deionized water, HF, HCl and O₃ water.

12. The method of claim 11, wherein said DHF solution comprises deionized water and HF mixed at a ratio between approximately 100:1 to 200:1.

13. The method of claim 10, wherein said projecting third oxide film comprises an etch rate greater than said first oxide film with respect to the DHF solution.
